(19) United States
(12) Patent Application Publication
(10) Pub. No.: US 2013/0039065 A1
(43) Pub. Date: Feb. 14, 2013

(54) SEMICONDUCTOR LIGHT-EMITTING ELEMENT MOUNTING MODULE, SEMICONDUCTOR LIGHT-EMITTING ELEMENT MODULE, MANUFACTURING METHOD OF SEMICONDUCTOR LIGHT-EMITTING ELEMENT MOUNTING MODULE, AND MANUFACTURING METHOD OF SEMICONDUCTOR LIGHT-EMITTING ELEMENT MODULE

(71) Applicants: YOSHIFUMI OKABE, KANAGAWA (JP); HIROMITSU KURIMOTO, KANAGAWA (JP); TORU WAGATSUMA, KANAGAWA (JP)

(72) Inventors: YOSHIFUMI OKABE, KANAGAWA (JP); HIROMITSU KURIMOTO, KANAGAWA (JP); TORU WAGATSUMA, KANAGAWA (JP)

(73) Assignee: KYOCERA CONNECTOR PRODUCTS CORPORATION, KANAGAWA (JP)

(21) Appl. No.: 13/554,073

(22) Filed: Jul. 20, 2012

(30) Foreign Application Priority Data
Jul. 25, 2011 (JP) 2011-162434

(51) Int. Cl. F21V 21/00; H05K 13/04; H05K 13/00; F21V 7/00; H05K 3/10

(52) U.S. Cl. 362/249.02; 362/382; 362/296.01; 29/849; 29/842; 29/832; 29/840

(57) ABSTRACT

A semiconductor light-emitting element mounting module includes a metal conductor plate including at least one connection surface formed on one side thereof, wherein a semiconductor light-emitting element is connectable to the connection surface; a pair of terminals provided away from the connection surface and which are connectable to the connection surface to be electrically conductive therewith; a surface-insulation portion formed from a resin material, wherein the surface-insulation portion covers the entire surface of the metal conductor plate except for the connection surface. The pair of terminals are connectable with a corresponding pair of terminals that are provided on another semiconductor light-emitting element mounting module.

### CROSS REFERENCE TO RELATED APPLICATION

The present invention is related to and claims priority of the following co-pending application, namely, Japanese Patent Application No. 2011-162434 filed on Jul. 25, 2011.

### BACKGROUND OF THE INVENTION

1. Field of the Invention

The present invention relates to a semiconductor light-emitting element mounting module to which a plurality of semiconductor light-emitting elements (LEDs) can be mounted, a semiconductor light-emitting element module, a manufacturing method of the semiconductor light-emitting element mounting module, and a manufacturing method of the semiconductor light-emitting element module.

2. Description of Related Art

In recent years, light fixtures which utilize LEDs (semiconductor light-emitting elements) have been used in various fields, such as for an interior light fixture or a backlight for used in an LCD monitor, etc.

A light fixture which utilizes LEDs is typically configured by arranging a large number of circuit boards (rigid substrates), onto which one or a plurality of LEDs are installed on one side, in a chain-like manner (either linear or planar), and connecting adjacent circuit boards with an electrical connector.

Examples of the related art are disclosed in Japanese Patent Domestic Announcement Nos. 2010-525523 and 2010-505232, and Japanese Patent Publication Nos. 2010-62556 and 2010-98302.

However, since the radiativity of the circuit boards (rigid substrates) that are utilized in the above-mentioned related art is far from being favorable, the light fixtures of the above-mentioned related art cannot efficiently radiate the heat generated by the LEDs.

Furthermore, the electrical conductive section (e.g., a circuit pattern) is exposed on the surface of the circuit board. Accordingly, if a metal thermal radiator plate for absorbing heat generated by the light fixture is provided close to the light fixture or provided on an inner side of a metal body for storing the light fixture, there is a danger of short-circuiting occurring between the radiator plate or metal body and the light fixture.

Furthermore, since a radiator plate cannot be installed close to the light fixture, a sufficient heat-radiating effect cannot be achieved in the case where a radiator plate is utilized.

### SUMMARY OF THE INVENTION

The present invention provides a semiconductor light-emitting element mounting module, a semiconductor light-emitting element module, a manufacturing method of the semiconductor light-emitting element mounting module, and a manufacturing method of the semiconductor light-emitting element module which exhibit excellent radiativity and have a greatly-reduced danger of short-circuiting even in the case where electrically conductive members (for example thermal radiator plates) are arrangement close to a thermal radiator plate.

According to an aspect of the present invention, a semiconductor light-emitting element mounting module is provided, including a metal conductor plate including at least one connection surface formed on one side thereof, wherein a semiconductor light-emitting element is connectable to the connection surface; a pair of terminals provided away from the connection surface and which are connectable to the connection surface to be electrically conductive therewith; a surface-insulation portion formed from a resin material, wherein the surface-insulation portion covers the entire surface of the metal conductor plate except for the connection surface, wherein the pair of terminals are connectable with a corresponding pair of terminals that are provided on another semiconductor light-emitting element mounting module.

Accordingly, heat from the semiconductor light-emitting elements (LEDs) can be efficiently received (absorbed) by the conductive plate (conductive part) due to the main parts of the semiconductor light-emitting mounting module (semiconductor light-emitting module) being configured of a metal conductive plate (conductive part) that has superior thermal conductivity and rigidity, and by the entire conductive plate (conductive part), except the connection surfaces thereof, being covered by a surface-insulation portion (first surface-insulation portion/second surface-insulation portion) formed from a resin material. Accordingly, heat generated by the LEDs is efficiently radiated externally through the conductive plate (conductive part) and the thin surface-insulation portion (first surface-insulation portion/second surface-insulation portion).

Furthermore, with exception to connection surfaces provided on one side (surface) of the conductive plate, since the entire surface of the conductive plate (conductive part) is covered by the thin surface-insulation portion (first surface-insulation portion/second surface-insulation portion), even if the other side of the conductive plate is arranged on a thermal radiator plate or an inner surface of a metal body that stores a semiconductor light-emitting mounting module (semiconductor light-emitting module), short-circuiting does not occur between the semiconductor light-emitting mounting module (semiconductor light-emitting module) and the thermal radiator plate or the metal body.

Furthermore, since it is possible (since short-circuiting does not occur) to provide the thermal radiator plate close to the semiconductor light-emitting mounting module (semiconductor light-emitting module), the thermal radiation effect is further enhanced by utilizing the thermal radiator plate.

It is desirable for the pair of terminals to be provided separately from the metal conductor plate.

Accordingly, a desired profile of the contact portions is possible since an improved flexibility in design of the contact portions is achieved.

It is desirable for the conductor plate to be an elongated plate member that extends linearly, wherein each end of the conductor plate, with respect to the elongated direction of the conductor plate, is provided with the pair of terminals.

Accordingly, a desired length of the semiconductor light-emitting mounting module can be achieved by connecting in a chain-like manner.

It is desirable for the surface-insulation portion to be provided around at least part of the periphery of the semiconductor light-emitting element, which is connected to the connection surface, with a reflective wall which reflects light that is emitted from the semiconductor light-emitting element.

It is possible for the reflective wall to be formed in an annular shape that surrounds the entire periphery of the connection surface.

Accordingly, since the surface-insulation portion is made out of resin, it is possible to select a material and color (and color tone) having a high reflectivity, and furthermore, it is easy to form the reflector plates into a desired shape. Therefore, the light emitted from the semiconductor light-emitting elements that are connected to the connection surfaces can be reflected in a desired direction by the reflector plates.

It is desirable for the conductor plate to be provided with a plurality of connection surfaces arranged in one direction, wherein each of the connection surfaces are provided mutually separate from each other, and each adjacent connection surface of the plurality of connection surfaces can be connected to each other to be electrically conductive therebetween.

Accordingly, a plurality of LEDs can be easily mounted.

In an embodiment, a semiconductor light-emitting element module is provided, including a semiconductor light-emitting element module having the above-described structure; at least one light-emitting element that is installed onto each of the connection surfaces; and wire bonding which connects each of the connection surfaces with the light-emitting elements, and each the adjacent connection surfaces to each other.

Accordingly, since each connection surface and each semiconductor light-emitting element, and each mutually adjacent connection surface are connected to each other by wire-bonding, the space (distance) between each semiconductor light-emitting element is narrower compared to the case where solder is used to connect the connection surfaces to the semiconductor light-emitting elements. Therefore, luminance irregularities in the semiconductor light-emitting element module can be reduced, and the luminance can be improved.

Furthermore, since it is unnecessary to carry out reflowing, when the semiconductor light-emitting elements are connected (installed) via the connection surfaces, there is no danger of the semiconductor light-emitting element modules receiving adverse influence (warpage, or tarnishing of the resin) due to heat, like in the case of soldering.

It is desirable for the surfaces of each of the light-emitting elements and the wire bonding are covered with a sealant that is formed from a transparent resin material.

Accordingly, the semiconductor light-emitting elements and the wire bonding can be protected with a sealant.

It is desirable for the semiconductor light-emitting element module to include a terminal covering portion which prevents an external part of each of the terminals from being exposed, by covering the periphery of each of the terminals, when the pair of terminals are connected to another pair of terminals or when the pair of terminals are connected to another conductive member.

Accordingly, since the terminals are covered by the terminal covering portion, the danger of short-circuiting between the terminals and other conductive members can be eliminated.

In an embodiment, a method of manufacturing a semiconductor light-emitting element mounting module is provided, including forming, using a molding die, a metal conductor plate provided with a carrier section which is supportable by the molding die and conductive portions on one surface of the metal conductor plate that have been integrated with the carrier section, wherein the conductive portions include at least one connection surface that is connectable to a semiconductor light-emitting element and cutoff bridges that integrate the carrier section with the connection surface, and a pair of terminals which are positioned separately from the connection surface and is connectable with the connection surface to be electrically conductive therewith; forming a first surface-insulation portion made of resin which connects the carrier section to the connection surface onto the surface of the conductor plate, except for the connection surface, while the carrier section is supported by the molding die; performing a primary cutting process in which the cutoff bridges are cut so that the carrier section is separated from the connection surface; forming a second surface-insulation portion made of resin onto the entire surface of the conductive portions while supporting the carrier section with the molding die; and performing a secondary cutting process in which the first surface-insulation portion is cut so that the carrier section is separated from the conductive portions.

It is desirable for the pair of terminals to be formed separately from the conductor plate.

It is desirable for the conductor plate to include an elongated plate member that extends linearly, wherein each end of the conductor plate, with respect to the elongated direction of the conductor plate, is provided with the pair of terminals.

It is desirable for the first surface-insulation portion to be provided around at least a part of the periphery of the semiconductor light-emitting element, which is connected to the connection surface, with a reflective wall which reflects light that is emitted from the semiconductor light-emitting element.

It is desirable for the reflective wall to be annular in shape and surround the entire periphery of the semiconductor light-emitting element that is connected to the connection surface.

It is desirable for the conductive portions to include a plurality of the connection surfaces, wherein a plurality of the cutoff bridges are connected to the plurality of the connection surfaces to integrate adjacent the connection surfaces, and the primary cutting process separates the adjacent the connection surfaces.

In an embodiment, a method of manufacturing a semiconductor light-emitting element module is provided, including the method of manufacturing a semiconductor light-emitting element mounting module according to the above-described structure; placing at least one the semiconductor light-emitting element on each of the connection surfaces; and connecting the semiconductor light-emitting elements to the connection surfaces, and connecting each the adjacent connection surfaces, respectively, to be electrically conductive therebetween.

It is desirable for the connecting of the semiconductor light-emitting elements to the connection surfaces and the connecting of each adjacent connection surface to be carried out using wire bonding.

After carrying out the connecting of the semiconductor light-emitting elements to the connection surfaces and the connecting of each the adjacent connection surfaces, it is desirable for the surfaces of the semiconductor light-emitting elements and the wire bonding to be covered with a sealant that is formed from a transparent resin.

After carrying out the connecting of the semiconductor light-emitting elements to the connection surfaces and the connecting of each the adjacent connection surfaces, it is desirable for the periphery of the terminals to be covered by a terminal covering portion which prevents an external part of each of the terminals from being exposed when the pair of terminals are connected to another pair of terminals or when is the pair of terminals are connected to another conductive member.

Accordingly, the above-described semiconductor light-emitting element mounting module and the semiconductor light-emitting element module can be easily manufactured.

Furthermore, since after forming a first surface-insulation portion on the conductive plate (conductive section) (after connecting the carrier portions, the connection surfaces and a pair of terminals by the first surface-insulation portion), the cutoff bridge is physically cut off, and the carrier portions, the connection surfaces and a pair of terminals are mutually separated, the positional precision of the connection surfaces with respect to the outer profile of the semiconductor light-emitting element mounting module (semiconductor light-emitting element module) can be improved. Accordingly, since each semiconductor light-emitting element can be precisely placed at the positioned intended at the design stage, luminance irregularities can be reduced.

### BRIEF DESCRIPTION OF THE DRAWINGS

The present invention will be discussed below in detail with reference to the accompanying drawings, in which:

FIG. 1 is a plan view of a conductor plate according to a first embodiment of the present invention;

FIG. 2 is an enlarged sectional view taken along the II-II line shown in FIG. 1, viewed in the direction of the appended arrows;

FIG. 3 is an enlarged sectional view taken along the III-III line shown in FIG. 1, viewed in the direction of the appended arrows;

FIG. 4 is an enlarged perspective view of a front end portion of the conductor plate, as viewed in an oblique direction from the front upper side thereof;

FIG. 5 is an enlarged perspective view of a rear end portion of the conductor plate, as viewed in an oblique direction from the rear lower side thereof;

FIG. 6 is a plan view showing a surface of the conductor plate covered with a first surface-insulation portion;

FIG. 7 is an underside plan view showing a surface of the conductor plate covered with a first surface-insulation portion;

FIG. 8 is an enlarged sectional view taken along the VIII-VIII line shown in FIG. 6, viewed in the direction of the appended arrows;

FIG. 9 is an exploded enlarged perspective view of a front end of the conductor plate and front terminals as viewed in an oblique direction from the front upper side thereof;

FIG. 10 is an exploded enlarged perspective view of a rear end of the conductor plate and rear terminals as viewed in an oblique direction from the rear lower side thereof;

FIG. 11 is an exploded enlarged perspective view of the front end of the conductor plate when the front terminals are temporarily attached to terminal insulation portions;

FIG. 12 is an exploded enlarged perspective view of the rear end of the conductor plate when the rear terminals are temporarily attached to terminal insulation portions;

FIG. 13 is an enlarged plan view of the conductor when a first cutting process has been performed and part of the first surface-insulation portion;

FIG. 14 is a plan view showing the surface of the conductor plate covered with a second surface-insulation portion;

FIG. 15 is an underside plan view showing the surface of the conductor plate covered with the second surface-insulation portion;

FIG. 16 is an enlarged sectional view, similar to that of FIG. 8, when the surface of the conductor plate covered with the second surface-insulation portion;

FIG. 17 is an enlarged perspective view of a front end of an LED mounting module when the surface of the conductor plate is covered with the second surface-insulation portion as viewed in an oblique direction from the front upper side thereof;

FIG. 18 is an enlarged perspective view of a rear end of an LED mounting module when the surface of the conductor plate is covered with the second surface-insulation portion as viewed in an oblique direction from the rear lower side thereof;

FIG. 19 is a plan view of the LED mounting module that has been completed upon a second cutting process being performed thereon;

FIG. 20 is an enlarged sectional view taken along the XX-XX line shown in FIG. 19, viewed in the direction of the appended arrows;

FIG. 21 is an enlarged sectional view taken along the XXI-XXI line shown in FIG. 19, viewed in the direction of the appended arrows;

FIG. 22 is an enlarged sectional view taken along the XXII-XXII line shown in FIG. 19, viewed in the direction of the appended arrows;

FIG. 23 is an enlarged sectional view taken along the XXIII-XXIII line shown in FIG. 19, viewed in the direction of the appended arrows;

FIG. 24 is an enlarged sectional view taken along the XXIV-XXIV line shown in FIG. 19, viewed in the direction of the appended arrows;

FIG. 25 is a perspective view of the LED mounting module as viewed in an oblique direction from the front upper side thereof;

FIG. 26 is a perspective view of the LED mounting module as viewed in an oblique direction from the rear lower side thereof;

FIG. 27 is a plan view of the LED mounting module when LED elements are placed onto each connection surface;

FIG. 28 is an enlarged sectional view taken along the XXVIII-XXVIII line shown in FIG. 27, viewed in the direction of the appended arrows;

FIG. 29 is an enlarged plan view of the LED module with the first and second surface-insulation portions omitted, and also a central portion thereof omitted;

FIG. 30 is an enlarged sectional view of the LED module that is similar to that of FIG. 8, in which a wire bonding is applied with a cover material mounted;

FIG. 31 is an exploded enlarged perspective view of both front and rear ends of the LED module, and front and rear end caps, as viewed in an oblique direction from the front upper side thereof;

FIG. 32 is an exploded enlarged perspective view of both front and rear ends of the LED module, and front and rear end caps, as viewed in an oblique direction from the rear lower side thereof;

FIG. 33 is an enlarged perspective view of the LED module with the front and rear end caps attached to both front and rear sides thereof, as viewed in an oblique direction from the front upper side thereof;

FIG. 34 is an enlarged perspective view of the LED module with the front and rear end caps attached to both front and rear sides thereof, as viewed in an oblique direction from the rear lower side thereof;

FIG. 35 is an enlarged perspective view of connecting portions (terminals) of two LED modules, as viewed in an oblique direction from the front upper side thereof;

FIG. 36 is an enlarged perspective view of connecting portions (terminals) of two LED modules, as viewed in an oblique direction from the rear lower side thereof;

FIG. 37 is an enlarged plan view of front and rear terminals when adjacent ends of two LED modules are connected to each other;

FIG. 38 is an underside plan view of an LED module (elongated light fixture) when mounted to a side of an LCD panel unit; and

FIG. 39 is a schematic diagram of conductor plates when a plurality of LED modules are connected together as a series circuit.

### DESCRIPTION OF THE EMBODIMENTS

An embodiment of the present invention will be hereinafter discussed with reference to the accompanying drawings. Note that in the explanations hereinbelow, the “upward”, “downward”, “left”, “right”, “forward” and “rearward” directions are based on the directions of the arrows that are indicated in the drawings.

In the illustrated embodiment, the present invention is applied to an LED module (semiconductor light-emitting element module) 10. The LED module 10 can be used as, e.g., a light source for an LCD panel unit 100 (see FIG. 38) that is a laminated unit having a rectangular shape, in a front elevational view, and configured of an LCD panel 101, a light guide plate 102 and a reflector plate 103. The LCD panel unit 100 of the illustrated embodiment is a so-called “edge-lighting” type in which light is incident onto a side surface of the light guide plate 102.

The LED module 10 is configured of at least one LED element (semiconductor light-emitting element) 80 mounted onto an LED mounting module (semiconductor light-emitting element mounting module) 15. The LED mounting module 15 is provided with a conductor plate 17, a first surface-insulation portion 35, a second surface-insulation portion 70, at least one LED element 80, wire bonding 81, and a sealant.

First detailed structure and a summary of the production of the LED mounting module 15 will be described hereinbelow.

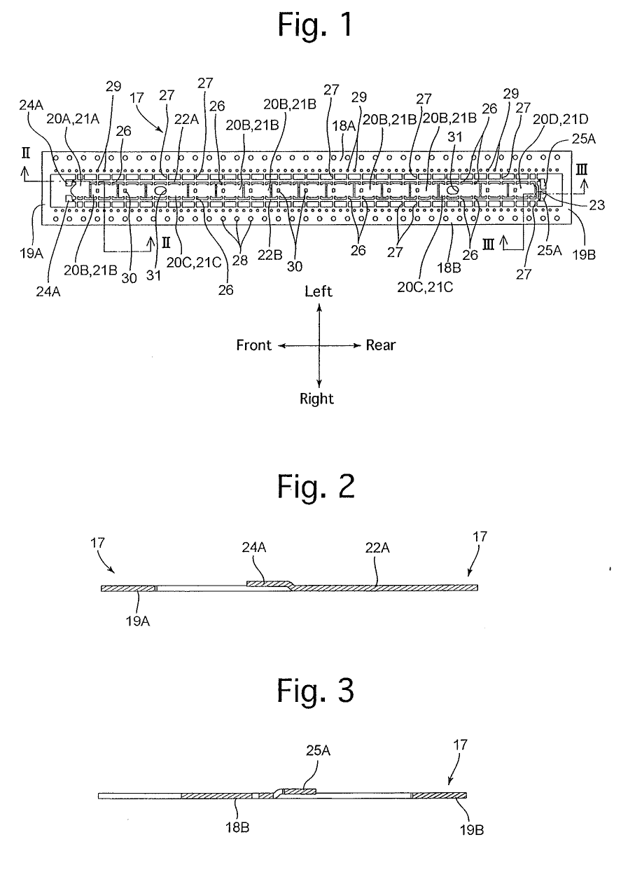

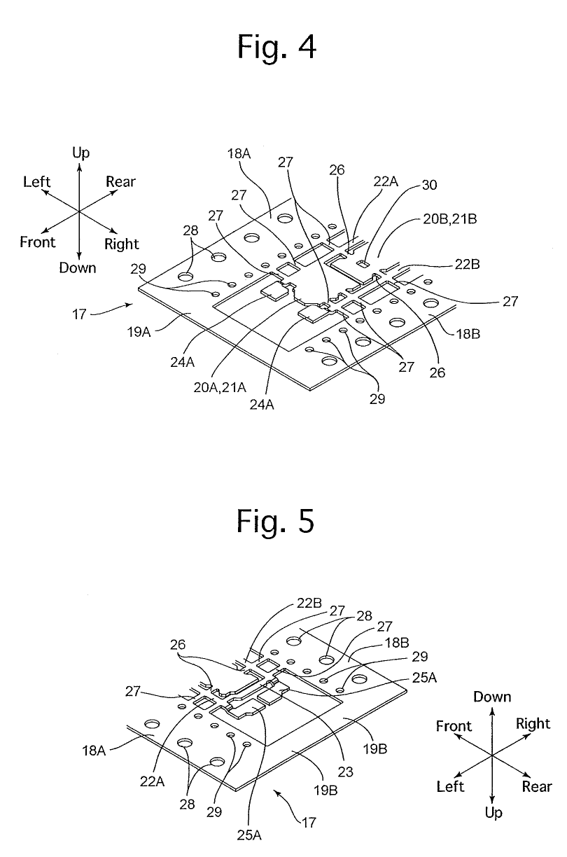

FIGS. 1 through 5 show the conductor plate 17 which constitutes a base material for the LED mounting module 15. The conductor plate 17 is made from a flat metal plate such as brass, beryllium copper or Corson copper alloy, etc., having superior conductive properties, thermal conductivity, rigidity, and also having elasticity (flexibility), and formed by a stamping process. Furthermore, since the surface of the conductor plate 17 has been silver plated, a favorable reflectivity (of light) of the surface of the conductor plate 17 is achieved. The overall shape of the conductor plate 17 is elongated to extend in the forward/rearward direction (e.g., the length in the forward/rearward direction can be approximately 10 cm), and is shaped as a flat plate except for terminal contact portions 24A and 25A (which will be discussed hereinafter). Each of the left and right sides of the conductor plate 17 are provided with forwardly/rearwardly extending carrier sections 18A and 18B, respectively. The front and rear ends of the conductor plate 17 are provided with carrier-connector sections 19A and 19B, respectively, which respectively connect the front and rear ends of the carrier sections 18A and 18B to each other. A total of sixteen connecting sections 20A, 20B, 20C and 20D (one connecting section 20A, twelve connecting sections 20B, two connecting sections 20C and one connecting section 20D), which are mutually separated from each other, are formed in a section of the conductor plate 17 that is surrounded by the carrier sections 18A and 18B, and the carrier-connector sections 19A and 19B so as to be arranged in the forward/rearward direction. The surfaces (upper surfaces) of the connecting sections 20A, 20B, 20C and 20D define connection surfaces 21A, 21B, 21C and 21D, respectively. The conductor plate 17 is provided with circuit-forming sections 22A and 22B which extend linearly in the forward/rearward direction are formed in a section that is surrounded by the carrier sections 18A and 18B and the carrier-connector sections 19A and 19B, in which the circuit-forming section 22A is positioned on the left side of the connecting sections 20B, 20C and 20D and the circuit-forming section 22B is positioned on the right side of the connecting sections 20A, 20B, 20C and 20D. The front end of the circuit-forming section 22A is connected to the connecting section 20A. Furthermore, the rear ends of the circuit-forming sections 22A and 22B are connected to each other via a rear-end connecting section 23 that extends in the left/right direction. A terminal contact 24A is connected to each of the front end of the connecting section 20A and the front end of the circuit-forming section 22B. As shown in FIGS. 2 and 4, the left and right terminal contacts 24A are positioned a step higher compared to the remainder of the conductor plate 17 while extending parallel to the remainder of the conductor plate 17. A terminal contact 25A is connected to each of the rear ends of the circuit-forming sections 22A and 22B. As shown in FIGS. 3 through 5, the left and right terminal contacts 25A are positioned a step higher compared to the remainder of the conductor plate 17 (and are positioned at the same vertical positions at those of the terminal contacts 24A) while extending parallel to the remainder of the conductor plate 17. The connecting sections 20A, 20B, 20C and 20D and the circuit-forming sections 22A and 22B are connected together by a large number of cutoff bridges 26 which extend in the left/right direction, and the carrier sections 18A and 18B and the circuit-forming sections 22A and 22B are connected together by a large number of the cutoff bridges 27 which extend in the left/right direction. Furthermore, a large number of round conveyor holes 28 are provided on the outer edge portions of the carrier sections 18A and 18B and are arranged in the forward/rearward direction, and a large number of round communicative holes 29, having a smaller diameter that that of the conveyor holes 28, are provided on the inner edge portions of the carrier sections 18A and 18B and are arranged in the forward/rearward direction. A rectangular communicative hole 30 is provided in each of the connecting sections 20B, and a screw-insertion slot 31 is formed in each of the connecting sections 20C.

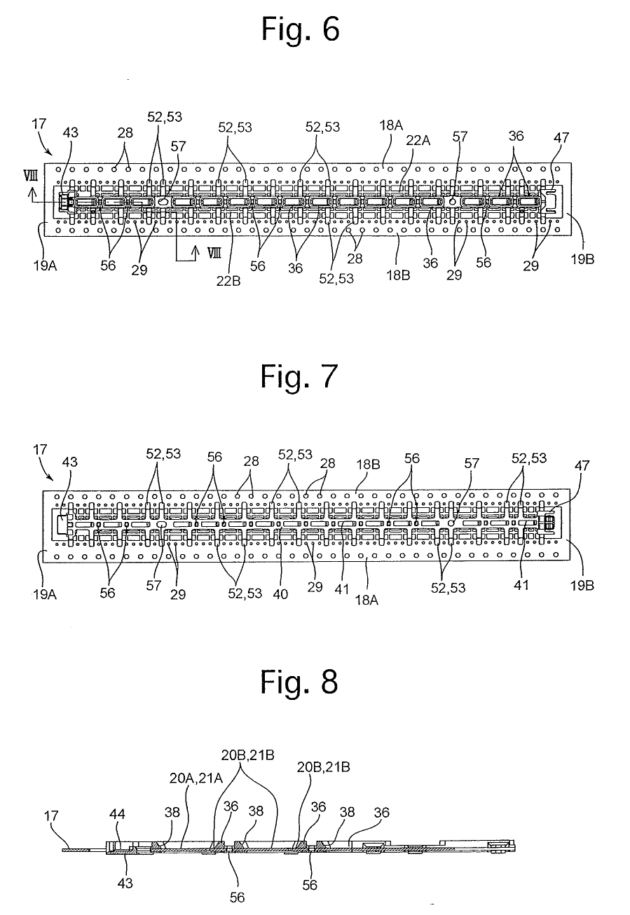

The conductor plate 17 having the above-described structure is engaged onto two sprockets of a conveyer apparatus (not shown) via the conveyor holes 28 so that the conductor plate 17 is conveyed in the rearward direction via rotation of the sprockets. Thereafter, upon the conductor plate 17 being conveyed to a predetermined position, a pair of primary molding dies (not shown) made of metal that are positioned above and below the conductor plate 17 close over the conductor plate 17 so that the conductor plate 17 is accommodated inside the primary molding dies. Thereupon, a large number of support pins (not shown) that are provided in primary molding dies are fitted into the respective conveyor holes 28, from which the sprockets have been removed, to thereby fix the conductor plate 17 inside the primary molding dies. Thereafter, injection molding (primary molding) using a resin material having high insulation properties, high reflectivity (of light) and high heat resistance is carried out in the primary molding dies. Subsequently, upon the resin material curing, each die of the primary molding dies is separated, upwardly and downwardly, from the conductor plate 17 to thereby remove the conductor plate 17 from the primary molding dies, thereby producing an integrated component in which the first surface-insulation portion 35 is integrally formed on the surface of the conductor plate 17 (see FIGS. 6 through 10).

As shown in the drawings, the first surface-insulation portion 35 is provided, on the upper surface of the conductor plate 17, with a total of sixteen LED storage portions 36 which bridge over the mutually adjacent connecting sections 20A, 20B, 20C, 20D, and the rear-end connecting section 23. The LED storage portions 36 are each formed as a substantially rectangular shape that is elongated in the forward/rearward direction. The connection surfaces 21A, 21B, 21C and 21D of the connecting sections 20A, 20B, 20C and 20D are formed on the inner sides of the LED storage portions 36, and a connection-surface exposure holes (recess) 37 for exposing the upper surface of the rear-end connecting section 23 are also formed on the inner sides of each LED storage portion 36. Furthermore, a reflective wall 38, which defines an inclined reflective surface that gradually enlarges the sectional area of the connection-surface exposure hole 37 from the lower edge toward the upper edge thereof, is formed on the inner periphery of each LED storage portion 36. The first surface-insulation portion 35 is provided, on the undersurface of the conductor plate 17, with an undersurface cover 40 which linearly extends in the forward/rearward direction and bridges over the mutually adjacent connecting sections 20A, 20B, 20C, 20D and the rear-end connecting section 23. The undersurface cover 40 is provided with a total of sixteen undersurface exposure holes 41 which expose the lower ends of adjacent connecting sections of the connecting sections 20A, 20B, 20C and 20D, and the rear-end connecting section 23.

Furthermore, a terminal insulation portion 43, which is integrated with the front-end LED storage portion 36 and the front end of the undersurface cover 40, is formed at the front end of the first surface-insulation portion 35. A connection recess 44 is formed on the upper surface of the terminal insulation portion 43. Furthermore, a pair of left and right terminal exposure holes 45 for exposing the terminal contacts 24A and a pair of left and right contact support grooves 46 that are provided in between the left and right terminal exposure holes 45 are formed on the upper surface of the terminal insulation portion 43. On the other hand, a terminal insulation portion 47, which is integrated with the rear-end LED storage portion 36 and the rear end of the undersurface cover 40, is formed at the rear end of the first surface-insulation portion 35. A connection projection 47b, which defines a space between left and right side members 47a, is formed at a central portion with respect to the left/right direction of the terminal insulation portion 47. A left and right pair of terminal recesses 48, each opening at the rear ends thereof, are formed on the undersurface of the connection projection 47b. Furthermore, a pair of left and right terminal exposure holes 49 for exposing the terminal contacts 25A are provided in the undersurface of the connection projection 47b. In addition, two provisional holding grooves 50 which respectively communicatively connect the left and right pair of terminal recesses 48 with the left and right terminal exposure holes 49 are formed on the undersurface of the connection projection 47b.

Furthermore, the first surface-insulation portion 35 is provided with a total of forty connector support members 52 (twenty on the left side and twenty on the right side) which linearly extend in the left direction and in the right direction, respectively, from respective left and right sides of the LED storage portions 36, the undersurface cover 40, the terminal insulation portions 43 and the terminal insulation portions 47. The end portions of the connector support members 52 respectively define a pair of connectors 53 which are bifurcated in the upward/downward directions and contact the upper and lower surfaces of the carrier sections 18A and 18B, respectively. Mutually facing surfaces of each pair of the connectors 53 are mutually connected to each other via the cured resin material through the corresponding communicative hole 29. Furthermore, a cutoff section 54 which fills the space defined between adjacent cutoff bridges 27 is formed at each front and rear end of each of the connector support members 52.

Communicative holes 56 and 57 for exposing, in the upper and lower directions, the communicative holes 30 and the screw-insertion slots 31 are formed in sections connecting adjacent LED storage portions 36 on the upper surface of the conductor plate 17 and are formed in sections corresponding to the communicative holes 30 and the screw-insertion slot 31 of the undersurface cover 40.

Upon the integrated component consisting of the first surface-insulation portion 35 integrally formed on the surface of the conductor plate 17 being removed from the primary molding die, front terminals 60 and rear terminals 64 are attached to this integrated component.

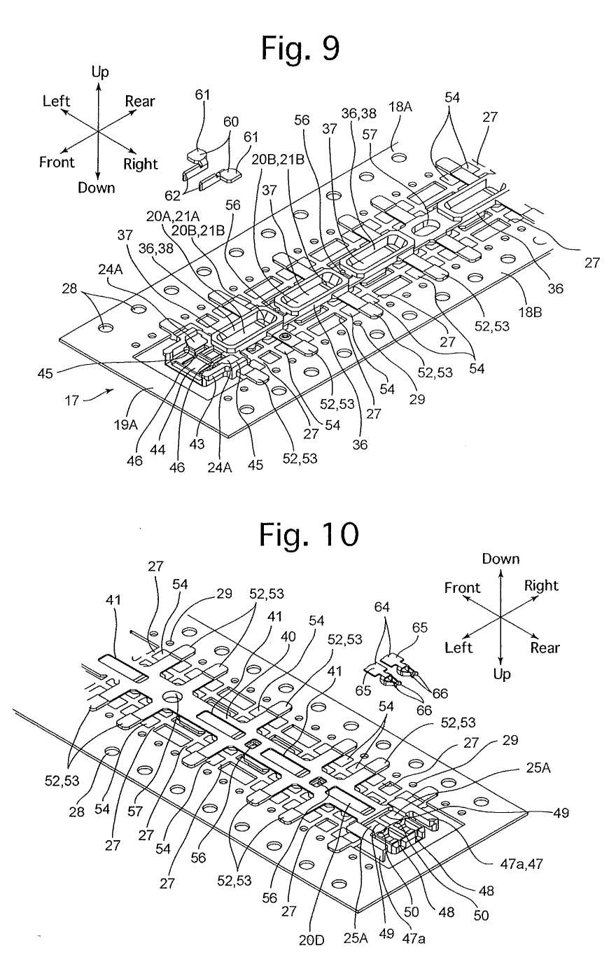

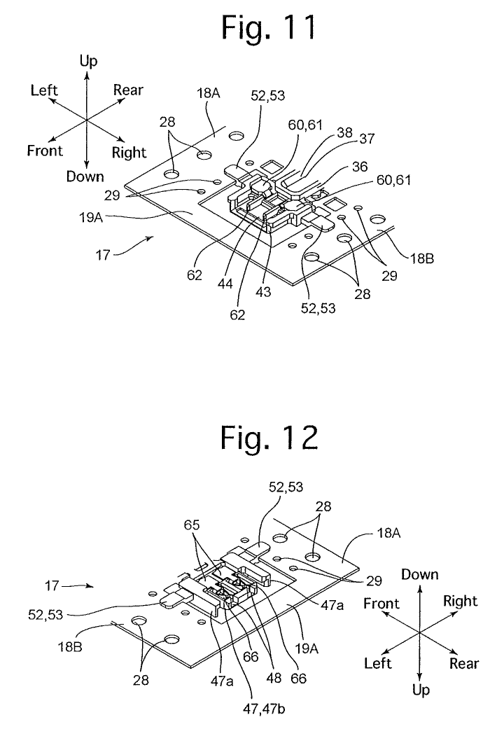

The left and right pair of front terminals 60 are formed into the shape shown in FIGS. 9 and 11 by stamp molding, for example, a phosphor bronze metal (or other type of metal) plate that is electrically conductive and has elasticity. The surface of the front terminals 60 is gold or tin plated. The front terminals 60 are each provided with a flat plate portion 61, constituting the rear end portion of each front terminal 60, and a contact portion 62 that extends from the flat plate portion 61 in the forward direction. As shown in FIG. 11, the left and right front terminals 60 are temporarily fixed (or can be permanently fixed by swaging) to the terminal insulation portion 43 by fitting the left and right contact portions 62 of the front terminals 60 into left and right contact support grooves 46, respectively, so that the front terminals 60 come in contact with the corresponding terminal contacts 24A through the terminal exposure holes 45 via the undersurface of the flat plate portion 61.

Similarly, the pair of left and right rear terminals 64 are formed into the shape shown in FIGS. 10 and 12 by stamp molding, for example, a phosphor bronze metal (or other type of metal) plate that is electrically conductive and has elasticity. The surface of the rear terminals 64 is gold or tin plated. The rear terminals 64 are each provided with a flat plate portion 65, constituting the front end portion of each rear terminal 64, and a pair of left and right contact portions 66 that extend rearwardly from a portion that extends rearwardly from the flat plate portion 65. As shown in the drawings, when the left and right contact portions 66 are in a free state, portions of the left and right contact portions 66 near the rear ends thereof are in mutual contact with each other. As shown in FIG. 12, the left and right rear terminals 64 are temporarily fixed (or can be permanently fixed by swaging) to the terminal insulation portion 47 by fitting portions (which are narrower than the flat plate portion 65) positioned between the flat plate portion 65 and the left and right contact portions 66 of each rear terminal 64 into corresponding provisional holding grooves 50, respectively. By temporarily fixing the left and right rear terminals 64 onto the terminal insulation portion 47, the left and right contact portions 66 are positioned in the corresponding left and right of terminal recesses 48, and the rear terminals 64 come in contact with the corresponding terminal contact 25A through the left and right terminal exposure holes 49 via the undersurface of the flat plate portions 65.

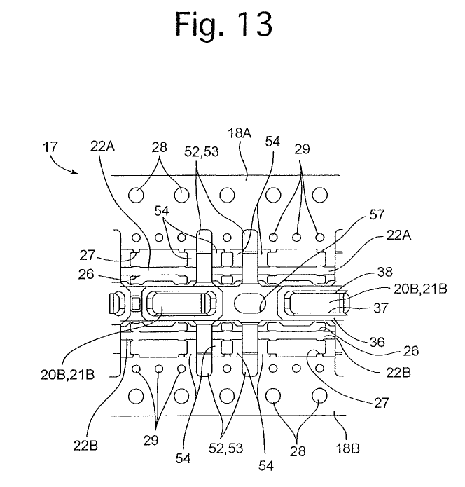

Upon the front terminals 60 and the rear terminals 64 being temporarily fixed to the integrated component consisting of the first surface-insulation portion 35 and the conductor plate 17, each of the cutoff bridges 26 and 27, the sections of the cutoff section 54 that are adjacent to the cutoff bridges 27, the connection end portions that are connected to the circuit-forming sections 22A of the rear-end connecting section 23 are primarily cut in a linear forward/rearward direction (see FIGS. 13 and 29) by a primary cutting device (not shown). Upon the primary cutting being performed, the connecting sections 20A, 20B, 20C and 20D physically separate from the circuit-forming section 22A, the connecting sections 20A, 20B, 20C and 20D physically separate from the circuit-forming section 22B, and the circuit-forming sections 22A and 22B physically separate from each other, as shown in FIG. 29.

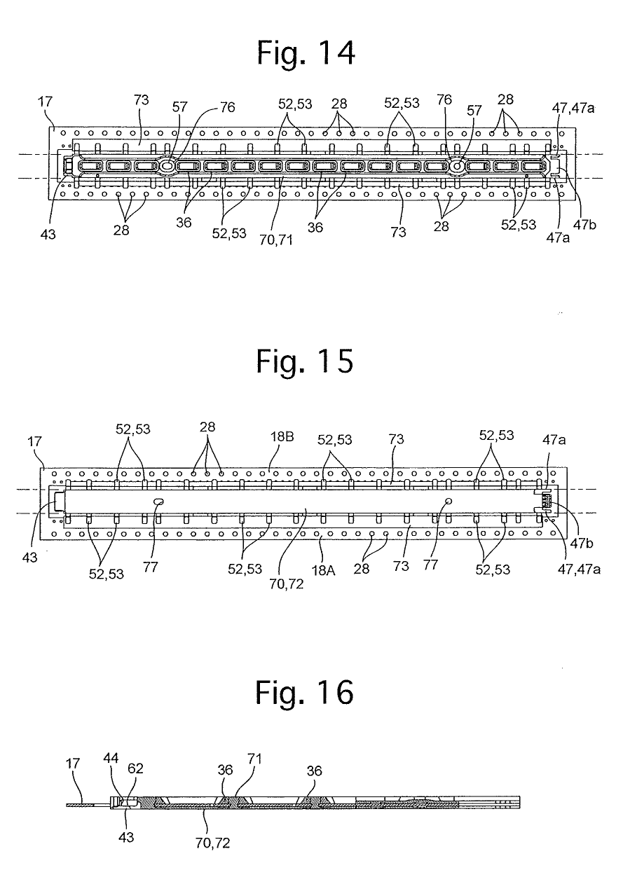

Upon completion of the primary cutting operation, the integrated component consisting of the conductor plate 17 and the first surface-insulation portion 35 is conveyed in a rearward direction until reaching a predetermined position. Thereafter, a pair of secondary molding dies (not shown) made of metal are positioned above and below the integrated component (the conductor plate 17 and the first surface-insulation portion 35) and are closed over the integrated component so as to be accommodated inside the pair of secondary molding dies. Thereupon, a large number of support pins (not shown) that are provided in secondary molding dies are fitted into the respective conveyor holes 28, to thereby fix the integrated component (the conductor plate 17 and the first surface-insulation portion 35) inside the secondary molding dies. Thereafter, injection molding (secondary molding) using a highly insulative resin material (e.g., a liquid crystal polymer) is carried out in the secondary molding dies. Subsequently, upon the resin material curing, each die of the secondary molding dies is separated, upwardly and downwardly, from the integrated component to thereby remove the integrated component from the secondary molding dies, thereby producing an integrated component in which the second surface-insulation portion 70 is integrally formed on the conductor plate 17 and the first surface-insulation portion 35 (see FIGS. 14 through 18).

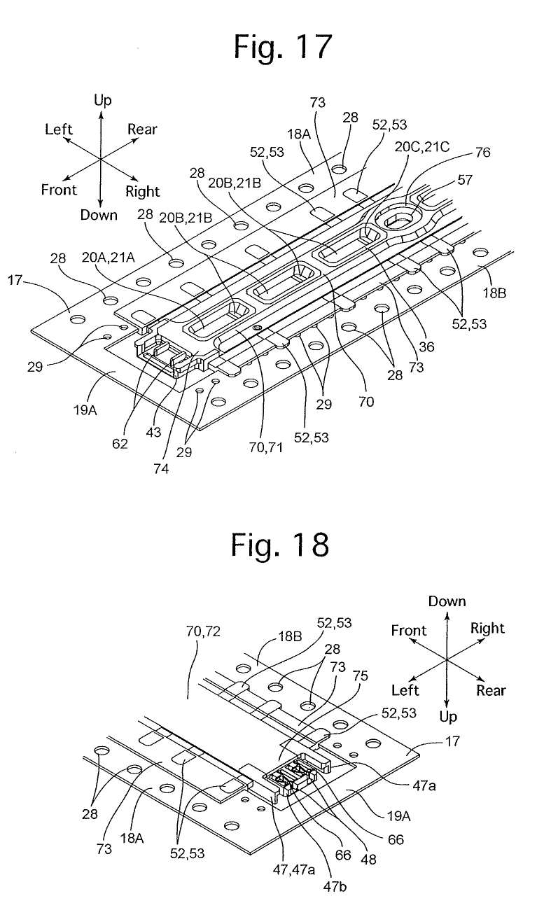

As shown in the drawings, the second surface-insulation portion 70 is integrally provided with an upper-surface covering portion 71 which covers the periphery of each LED storage portion 36 on the upper surface of the conductor plate 17 and linearly extends in the forward/rearward direction, an undersurface covering portion 72 which covers the entirety of the undersurface cover 40 on the undersurface of the conductor plate 17 and linearly extends in the forward/rearward direction, and (left and right) carrier connecting portions 73 which extend along the left and right sides of the left and right end portions of the upper-surface covering portion 71 and the undersurface covering portion 72, respectively, cover the upper and lower surfaces of the inner edges of the carrier sections 18A and 18B, and cover each connector 53. A terminal covering portion 74 which covers the surface of the flat plate portion 61 of each front terminal 60 is formed on the front end of the upper-surface covering portion 71, and a terminal covering portion 75 which covers the surface of the flat plate portion 65 of each rear terminal 64 is formed on the rear end of the undersurface covering portion 72 (see FIGS. 17 and 18). Furthermore, communicative-hole exposing holes 76 and 77 are formed in the section corresponding to the communicative holes 57 through the upper-surface covering portion 71 and the undersurface covering portion 72. In addition, parts of the second surface-insulation portion 70 are cured in the inner portions of each of the communicative holes 29, 30 and 56, so that these cured parts connect the upper-surface covering portion 71 with the undersurface covering portion 72.

Since the second surface-insulation portion 70 (carrier connecting portions 73) covers the surfaces of the circuit-forming sections 22A and 22B, and the cutoff end surfaces of the cutoff bridges 26 and 27, when the secondary molding is carried out, the entire surface of the conductor plate 17 except for the upper surfaces of the connection surfaces 21A, 21B, 21C and 21D and the rear-end connecting section 23, the flat plate portion 61 of the front terminals 60, and the flat plate portion 65 of the rear terminals 64 are covered by the first surface-insulation portion 35 and the second surface-insulation portion 70.

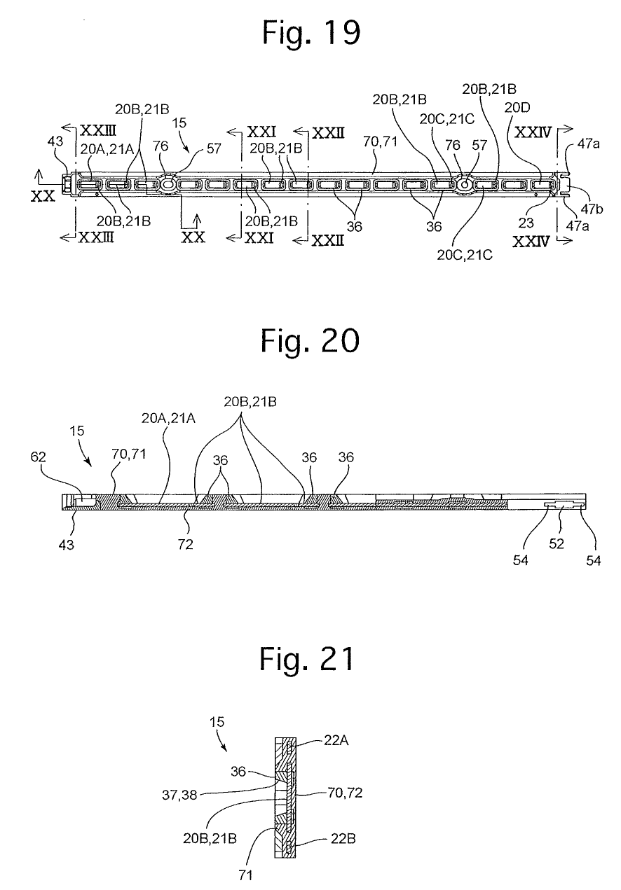

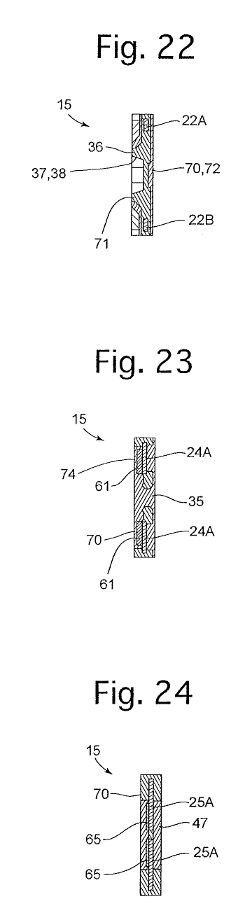

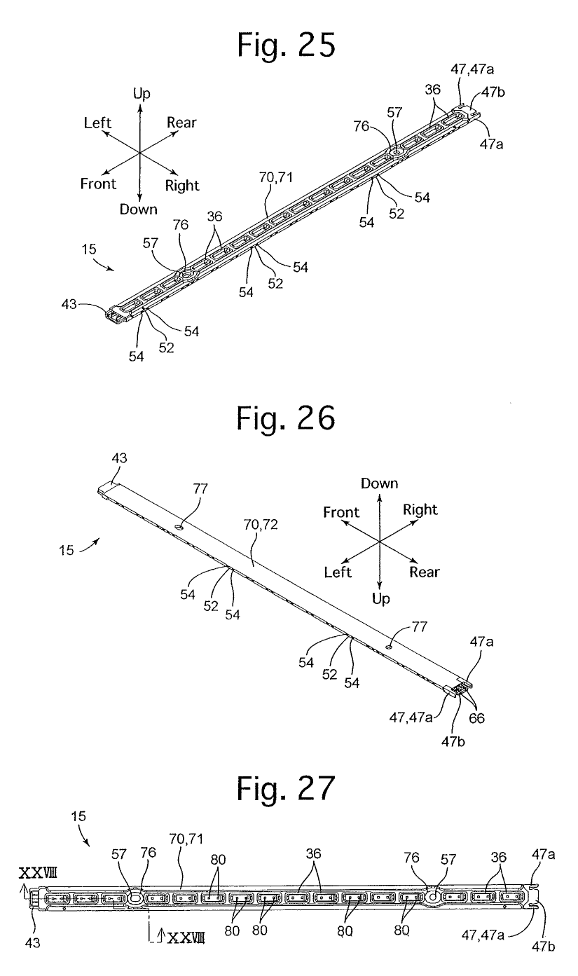

Upon the secondary molding being completed, the conductor plate 17, the first surface-insulation portion 35 and the second surface-insulation portion 70 are cut along straight lines (the two-dot chain lines shown in FIGS. 14 and 15) extending in the forward / rearward direction through the connecting sections between the left and right side edge portions of the upper-surface covering portion 71 and the undersurface covering portion 72 and the carrier connecting portions 73 (the connecting ends of the upper-surface covering portion 71 and the undersurface covering portion 72 of the carrier connecting portions 73) by a secondary cutting device (not shown). Subsequently, a completed LED mounting module 15 having the shape shown in FIGS. 19 through 26 is achieved. Furthermore, since the carrier connecting portions 73 are firmly (strongly) fixed to the carrier sections 18A and 18B by the parts of the second surface-insulation portion 70 that have been cured in the inner portions of the communicative holes 29, it is possible to carry out the cutting process in a stable manner (so that the carrier connecting portions 73 do not peel off or break away from the carrier sections 18A and 18B).

Since, as described above, since the entire surface of the conductor plate 17 except for the upper surfaces of the connection surfaces 21A, 21B, 21C and 21D and the rear-end connecting section 23, the flat plate portion 61 of the front terminals 60, and the flat plate portion 65 of the rear terminals 64 are covered by the first surface-insulation portion 35 and the second surface-insulation portion 70 at the stage where the secondary molding is carried out, the metal members that are exposed at the surface of the LED mounting module 15 are the connection surfaces 21A, 21B, 21C and 21D, the rear-end connecting section 23, the contact portion 62 and the parts of the rear terminals 64 other than the flat plate portions 65 (FIGS. 21 through 26).

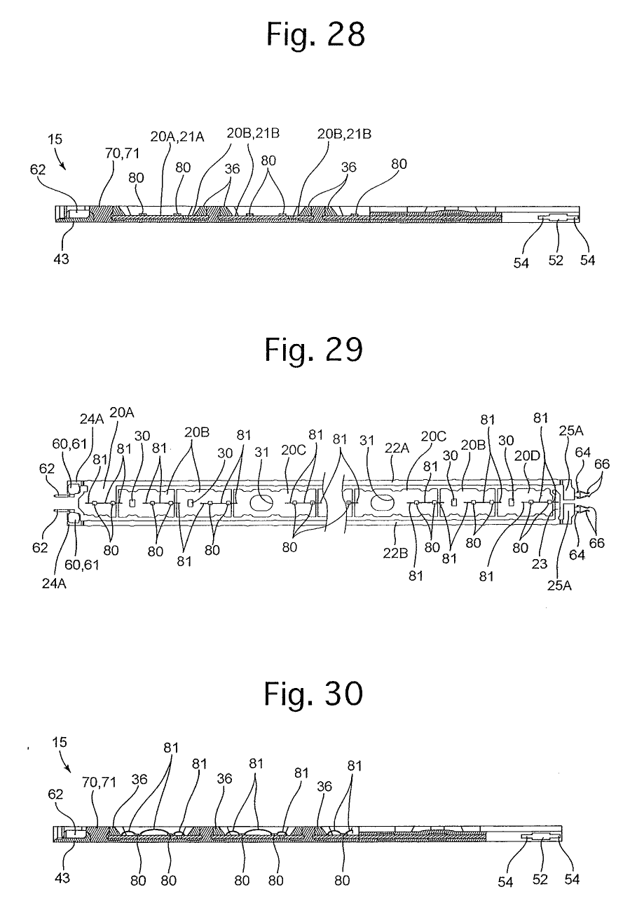

Thereafter, as shown in FIGS. 27 through 29, two LED elements 80, each having a light-emitting surface on upper surface thereof, are placed onto the upper surface of each of the connecting sections 20A, 20B, 20C and 20D (connection surfaces 21A, 21B, 21C and 21D) of the completed LED mounting module 15 (also possible to place two LED elements 80 on the upper surface of the rear-end connecting section 23), and each of the LED elements 80 are attached to the connection surfaces 21A, 21B, 21C and 21D by adhesive or by using a heat transfer sheet.

Furthermore, as shown in FIGS. 29, 30 and 31, the connecting sections 20A, 20B, 20C and 20D (connection surfaces 21A, 21B, 21C and 21D) are connected to the conductors (pads) of the LED elements 80 by the plurality of wire bondings 81 formed from a conductive metal material (e.g., metal or aluminum). More specifically, each set of two LED elements 80 that are placed onto the connection surfaces 21A, 21B, 21C and 21D are connected to the connection surfaces 21A, 21B, 21C and 21D that the LED elements 80 themselves are placed on, and each LED element 80 thereof that is positioned at the rear ends are connected to adjacent connection surfaces 21B, 21C and 21D or the rear-end connecting section 23 that are positioned behind the connection surfaces 21A, 21B, 21C and 21D onto which the LED elements 80 themselves are placed.

Subsequently, the surfaces of each LED element 80 and the wire bondings 81, and the upper surfaces of the connection surfaces 21A, 21B, 21C and 21D and the rear-end connecting section 23 are covered with a sealant (not shown) formed of a thermoset resin or an ultraviolet curable resin, etc., having transparent and insulative properties. Accordingly, the LED elements 80 and the wire bondings 81 are firmly mounted to the connection surfaces 21B, 21C and 21D and the rear-end connecting section 23.

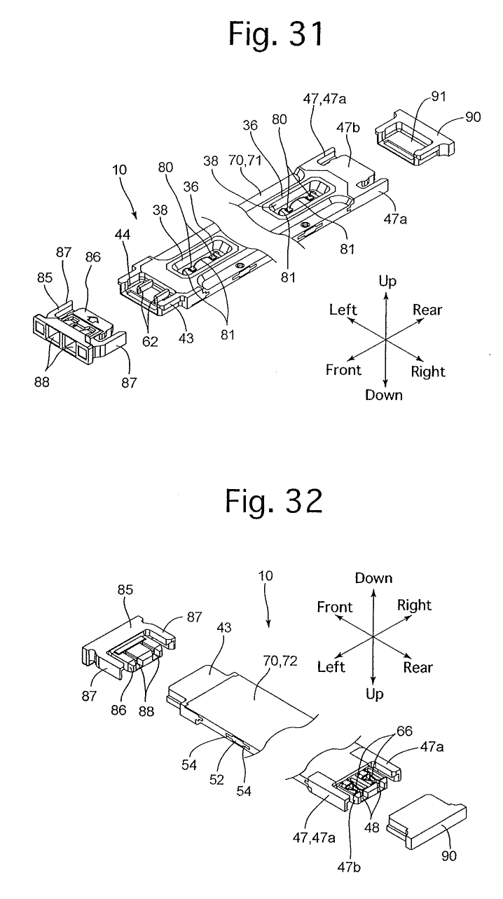

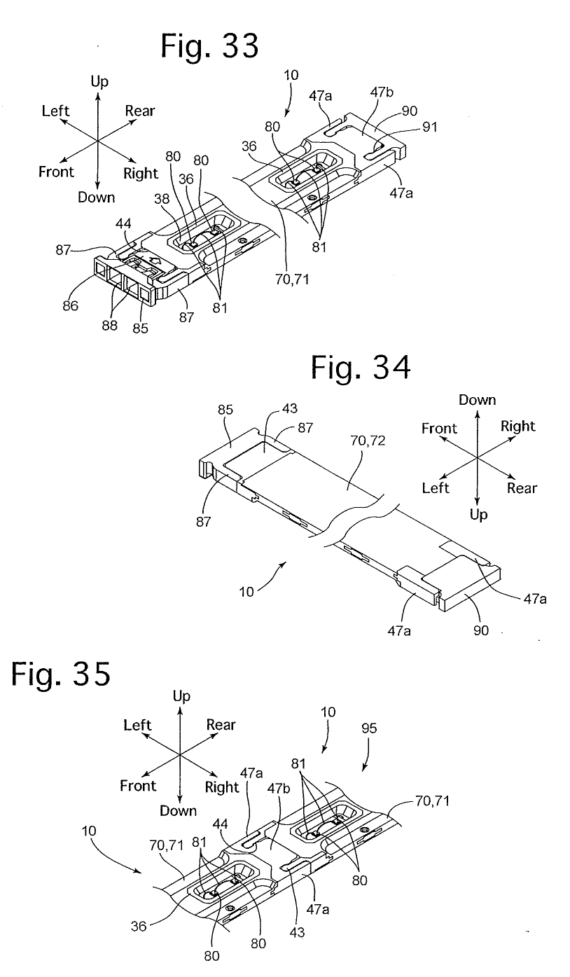

As shown in FIGS. 31 through 34, end caps 85 and 90 are detachably attached to the front and rear ends of the LED module 10, respectively.

The end cap 85 is an integrally molded component made from an insulative resin material and is provided with an engagement projection 86 and a pair of engagement side-projections 87 respectively positioned on the left and right sides of the engagement projection 86. A pair of left and right through-channels 88 are formed on the end cap 85. The front end of each through-channel 88 is opened at the front-end surface of the end cap 85, and the rear portion of each through-channel 88 is formed as a groove that is open at the undersurface and rear surface of the engagement projection 86.

The end cap 90 is an integrally molded component made from an insulative resin material and is provided in the upper surface at the front end portion thereof with an engagement recess 91.

The end cap 85 is attachable to the terminal insulation portion 43 by fitting the engagement projection 86 into the connection recess 44 and by engaging the left and right engagement side-projections 87, while being elastically deformed, with the respective outer left and right sides of the terminal insulation portion 43. When the end cap 85 is attached to the terminal insulation portion 43, the left and right contact portions 62 are positioned inside the through-channels 88. On the other hand, the end cap 90 is attachable to the terminal insulation portion 47 by fitting the engagement recess 91 onto the connection projection 47b and by engaging the left and right left and right side members 47a, while being elastically deformed, with the respective outer left and right sides of the end cap 90. When the end cap 90 is attached to the terminal insulation portion 47, the rear terminals 64 (the parts of the rear terminals 64 other than the flat plate portions 65) are completely covered by the terminal insulation portion 47 and the end cap 90.

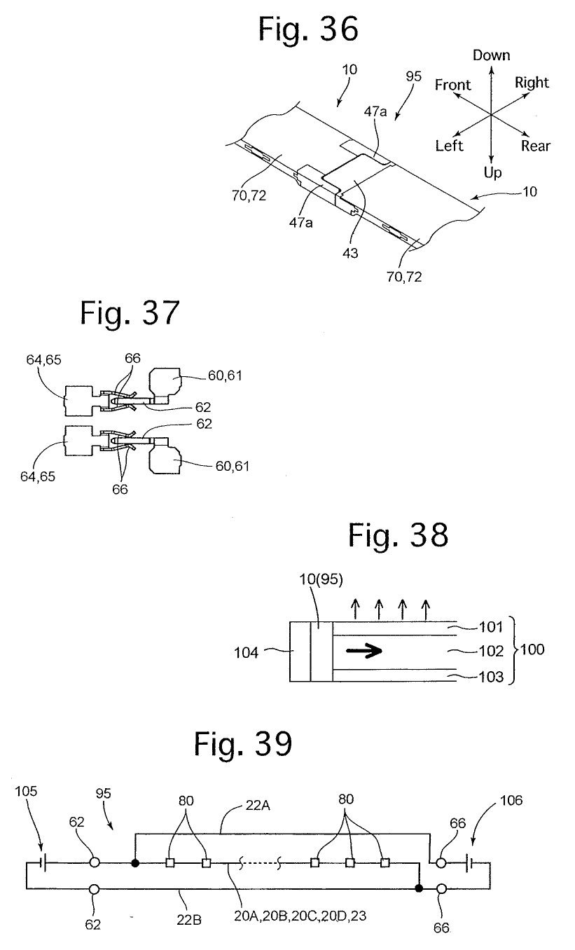

A terminal insulation portion 47 of a LED module 10 is connectable with a terminal insulation portion 43 of another (adjacent) LED module 10. Namely, as shown in FIGS. 35 and 36, by fitting the connection projection 47b into the connection recess 44 and engaging the left and right side members 47a, which being elastically deformed, with respective left and right outer sides of the terminal insulation portion 43, the terminal insulation portion 43 and the terminal insulation portion 47 can be mutually connected to each other. When the terminal insulation portions 43 and 47 are connected to each other, the contact portions 62 of the front terminals 60 are inserted in between each left and right pairs of contact portions 66 of each corresponding rear terminal 64, so as to contact while respectively expanding (elastically deforming) each pair of contact portions 66, as shown in FIG. 37. Furthermore, since the upper surfaces of the contact portions 62 are covered by the upper surfaces of the connection projection 47b, and since the undersurfaces of the left and right contact portions 66 are covered by the bottom surface of the connection recess 44, the surrounding area of the front terminals 60 and the rear terminals 64 are completely covered by the connection recess 44 and the connection projection 47b.

Accordingly, a terminal insulation portion 43 of yet another LED module 10 can be connected to the terminal insulation portion 47 of the LED module 10 to which the above-mentioned terminal insulation portion 43 is connected. In other words, it is possible to linearly connect a plurality of LED modules 10 to thereby configure a long light fixture 95 that is elongated in the forward/rearward direction.

The elongated light fixture 95 that has been assembled as described above (with a end cap 85 attached to the LED module 10 that is positioned at the front end) is connected to one end edge of an LCD panel unit 100, having a rectangular shape as viewed in a front elevation, with the elongating direction of the light fixture 95 orientated vertically, each LED element 80 faces a side end surface of the light guide plate 102, and a thermal radiator plate 104 of a display device (e.g., an LCD television) into with the LCD panel unit 100 is in-built can be connected to the undersurface covering portion 72 of each LED module 10 (see FIG. 38). In such a case, the elongated light fixture 95 can be fixed to a mounting member by stop screws (not shown) which are inserted through the screw-insertion slots 31 (and the communicative holes 57, and the communicative-hole exposing holes 76 and 77) of each LED module 10 and are screw-engaged with female screw holes provided in the mounting member (not shown) that is built into the display device. For example, as shown in the schematic diagram of FIG. 39, a cathode terminal of a direct current power source 105 is connected to the contact portion 62 that is connected to the circuit-forming section 22A of one end of the LED module 10 (the LED module 10 which has the end cap 85 attached thereto) through one through-channel 88 of the end cap 85, and an anode terminal of the direct current power source 105 is connected to the contact portion 62 that is connected to the circuit-forming section 22B of the LED module 10 through the other through-channel 88 of the end cap 85, via cables (not shown), etc.; furthermore, a cathode terminal of a direct current power source 106 is connected to the contact portion 66 that is connected to a circuit-forming section 22A of the other end of the LED module 10, and an anode terminal of the direct current power source 106 is connected to the contact portion 66 that is connected to the circuit-forming section 22B of the LED module 10. Accordingly, when the direct current power sources 105 and 106 are connected to the elongated light fixture 95, a series circuit is formed on the conductive portions (the connecting sections 20A, 20B, 20C and 20D, the circuit-forming sections 22A and 22B, the rear-end connecting section 23, and the terminal contacts 24A and 25A) of the conductor plate 17 of the LED module 10.

Accordingly, when a main switch (not shown) of the LCD panel unit 100, to which the direct current power sources 105 and 106 are connected, is turned ON, since current flows to the connecting sections 20A, 20B, 20C and 20D, the circuit-forming sections 22A and 22B, and the rear-end connecting section 23 (the series circuit) of the elongated light fixture 95 (of each LED module 10) from the direct current power sources 105 and 106 via the above-mentioned cables, the LED elements 80 which are provided in the above-mentioned series circuit emit light. The illumination light which each LED element 80 emits is reflected by the reflective wall 38 of each LED storage portion 36 that surrounds each LED element 80 and is reflected by the connection surfaces 21A, 21B, 21C and 21D, so that the illumination light is diffused radially. Furthermore, the illumination light proliferates along the light guide plate 102 and is further reflected by the reflector plate 103 to be reflected toward the LCD panel 101, and the LCD panel 101 performs a displaying operation.

In the above-described LED module 10 of the illustrated embodiment, since the conductive portions of the metal conductor plate 17 that has superior thermal conductivity and rigidity constitutes the major part of the LED mounting module 15, and since the entire upper surface of the conductor plate 17 except for upper surfaces of the connection surfaces 21A, 21B, 21C and 21D, and the upper surface of the rear-end connecting section 23, the flat plate portions 61 of the front terminals 60, and the flat plate portions 65 of the rear terminals 64 are covered by the resin first surface-insulation portion 35 and the resin second surface-insulation portion 70, heat generated by the LED elements 80 can be efficiently received by the conductive portions of the conductor plate 17. Accordingly, heat generated by each LED element 80 efficiently radiates externally from the LED mounting module 15 (LED module 10) via the conductor plate 17 (conductive portions) and the thin first surface-insulation portion 35 and thin the second surface-insulation portion 70.

Furthermore, since the entire underside of the LED mounting module 15 (LED module 10) is covered by the first surface-insulation portion 35 and the second surface-insulation portion 70, except for the flat plate portions 65 of the rear terminals 64, even if the thermal radiator plate 104 or an inner surface of a metal body (e.g., a metal body of the above-mentioned display device) for housing the LED module 10 is provided on the undersurface of the LED mounting module 15 (LED module 10), short-circuiting between the LED mounting module 15 (LED module 10) and thermal radiator plate 104 or the metal body does not occur.

Furthermore, since it is possible for the thermal radiator plate 104 to be positioned close to the LED mounting module 15 (LED module 10) (since short-circuiting does not occur), by utilizing the thermal radiator plate 104, a more effective heat dissipation can be achieved than in the case of only having the LED mounting module 15 (LED module 10) without the thermal radiator plate 104.

Furthermore, since the first surface-insulation portion 35 is formed from resin, it is possible to select a resin material therefor that has a high reflectivity and it is possible to select a desired color (or color tone) that has a high reflectivity, and it is also easy to form the LED storage portions 36 (reflective walls 38) into a desired shape. Accordingly, the illumination light emitted from the LED elements 80 that are connected to the connection surfaces 21A, 21B, 21C and 21D can be reflected by the reflective walls 38 at a desired direction.

Furthermore, since the first surface-insulation portion 35 and the second surface-insulation portion 70 are formed while the carrier sections 18A and 18B of the conductor plate 17 are supported by support pins of the primary molding die and the secondary molding die, the conductor plate 17 does not easy warp when the first surface-insulation portion 35 and the second surface-insulation portion 70 are being formed.

Furthermore, since the connection surfaces 21A, 21B, 21C and 21D and the LED elements 80 are connected to each other with wire bonding 81, the space (distance) between each LED element 80 can be reduced compared to the case where the LED elements 80 are connected to the connection surfaces 21A, 21B, 21C and 21D using solder. Accordingly, luminance irregularities of the LED module 10 are reduced, and the luminance can be improved.

Furthermore, since it is unnecessary to carry out reflowing, as in the case where soldering is used, when the LED elements 80 are connected to (installed onto) the connection surfaces 21A, 21B, 21C and 21D, there is little danger of heat adversely affecting (e.g., warping, or reduction in the reflectivity due to the color of the resin changing) the LED module 10.

In addition, since the connection surfaces 21A, 21B, 21C and 21D and the rear-end connecting section 23 are covered by the above-mentioned sealant which is formed from an insulative material, the LED elements 80 and the wire bonding 81 can be protected thereby, and the risk of the connection surfaces 21A, 21B, 21C and 21D short-circuiting with other conductive members that are provided around the LED module 10 can be eliminated.

Furthermore, since after the first surface-insulation portion 35 has been formed on the conductor plate 17 that is produced as an integrated component (after the carrier sections 18A and 18B, the connection surfaces 21A, 21B, 21C and 21D, the circuit-forming sections 22A and 22B have mutually connected to each other via the first surface-insulation portion 35), the cutoff bridges 26 and 27 are cut, and the carrier sections 18A and 18B, the connection surfaces 21A, 21B, 21C and 21D, and the circuit-forming sections 22A and 22B mutually separate from each other, a favorable positional precision of the connection surfaces 21A, 21B, 21C and 21D with respect to the outer profile of the LED module 10 can be achieved. Accordingly, since the LED elements 80 can be provided (positioned) in a highly precise manner at their designed positions, luminance irregularities can be reduced.

Additionally, since the LED elements 80 are arranged in a series circuit that is formed on the LED mounting module 15, it is possible to reduce luminance irregularities of the LED elements 80.

The present invention is not limited to above-described embodiment; the present invention can be applied while making various changes to above-described embodiment.

For example, the conductor plate 17 can be formed from a metal material other than that described above while having superior conductive properties, thermal conductivity and rigidity. Furthermore, the front terminals 60 and/or the rear terminals 64 can be formed integrally with the conductor plate 17.

The number of connecting sections 20A, 20B, 20C and 20D (connection surfaces 21A, 21B, 21C and 21D) that are formed on one conductor plate 17 is not limited to the number illustrated in the above-described embodiment, and can be one or a plurality thereof (other than sixteen).

The conductor plate 17 can be alternatively plated with a plating other than silver, e.g., gold or tin plating is also suitable.

Furthermore, the profile (shape) of the LED storage portions 36 (reflective walls 38) do not necessarily have to be annular in shape and surround the entire periphery of the respective LED elements 80, non-annular shaped LED storage portions 36 (reflective walls 38) that surround only part of the periphery of the LED elements 80 are also acceptable.

Furthermore, by changing the type (position) of the cutoff bridges 26 and 27 that are formed on the conductor plate 17 during the above-described stamping process, various types of circuits can be easily configured on the conductor plate 17 (conductive portions).

Alternatively, when the conductor plate 17 is formed, the connecting sections 20A, 20B, 20C and 20D can be continuously formed as an integral elongated connection portion, and thereafter, elongated grooves which expose elongated connection portions on the upper surface (connection surfaces) along the entire length of the conductor plate 17 can be formed in the first surface-insulation portion 35 and the second surface-insulation portion 70, and the LED elements 80 can be mounted at the sections exposed by such elongated grooves.

Furthermore, the LCD panel unit 100 can be a type in which the LED module 10 is positioned immediately behind the light guide plate 102 (in which the LED elements 80 face the light guide plate 102 and the reflector plate 103 is omitted).

Furthermore, the LED mounting module 15 (conductor plate 17) can be made to have a curved arc shape. In such a case, a circular or circular arc illumination fixture can be obtained by connecting a plurality of LED modules 10 (LED mounting modules 15) to each other.

Furthermore, soldering can be used instead of the wire bonding 81.

In addition, the LED module 10 can be applied to a device/apparatus other than a display device.

Other obvious changes may be made in the specific embodiments of the present invention described herein, such modifications being within the spirit and scope of the invention claimed. It is indicated that all matter contained herein is illustrative and does not limit the scope of the present invention.

What is claimed is:

1. A semiconductor light-emitting element mounting module, comprising:
a metal conductor plate including at least one connection surface formed on one side thereof, wherein a semiconductor light-emitting element is connectable to said connection surface;
a pair of terminals provided away from said connection surface and which are connectable to said connection surface to be electrically conductive therewith;
a surface-insulation portion formed from a resin material, wherein said surface-insulation portion covers the entire surface of said metal conductor plate except for said connection surface; and
wherein said pair of terminals are connectable with a corresponding pair of terminals that are provided on another semiconductor light-emitting element mounting module.

2. The semiconductor light-emitting element mounting module according to claim 1, wherein said pair of terminals are provided separately from said metal conductor plate.

3. The semiconductor light-emitting element mounting module according to claim 1, wherein said conductor plate comprises an elongated plate member that extends linearly;
wherein each end of said conductor plate, with respect to the elongated direction of said conductor plate, is provided with said pair of terminals.

4. The semiconductor light-emitting element mounting module according to claim 1, wherein said surface-insulation portion is provided around at least part of the periphery of said semiconductor light-emitting element, which is connected to said connection surface, with a reflective wall which reflects light that is emitted from said semiconductor light-emitting element.

5. The semiconductor light-emitting element mounting module according to claim 4, wherein said reflective wall is formed in an annular shape that surrounds the entire periphery of said connection surface.

6. The semiconductor light-emitting element mounting module according to claim 1, wherein said conductor plate is provided with a plurality of said connection surfaces arranged in one direction;
wherein each of said connection surfaces are provided mutually separate from each other, and
wherein each adjacent connection surfaces of said plurality of connection surfaces can be connected to each other to be electrically conductive therebetween.

7. A semiconductor light-emitting element module, comprising:
a semiconductor light-emitting element module according to claim 6;
at least one light-emitting element that is installed onto each of said connection surfaces; and
wire bonding which connects each of said connection surfaces with said light-emitting elements, and each said adjacent connection surfaces to each other.

8. The semiconductor light-emitting element module according to claim 7, wherein the surfaces of each of said light-emitting elements and said wire bonding are covered with a sealant that is formed from a transparent resin material.

9. The semiconductor light-emitting element module according to claim 7, further comprising a terminal covering portion which prevents an external part of each of said terminals from being exposed, by covering the periphery of each of said terminals, when said pair of terminals are connected to another pair of terminals or when said pair of terminals are connected to another conductive member.

10. A method of manufacturing a semiconductor light-emitting element mounting module, comprising:
forming, using a molding die, a metal conductor plate provided with a carrier section which is supportable by the molding die and conductive portions on one surface of said metal conductor plate that have been integrated with said carrier section, wherein said conductive portions include at least one connection surface that is connectable to a semiconductor light-emitting element and cutoff bridges that integrate said carrier section with said connection surface, and a pair of terminals which are positioned separately from said connection surface and is connectable with said connection surface to be electrically conductive therewith;
forming a first surface-insulation portion made of resin which connects said carrier section to said connection surface onto the surface of said conductor plate, except for said connection surface, while said carrier section is supported by said molding die;
performing a primary cutting process in which said cutoff bridges are cut so that said carrier section is separated from said connection surface;
forming a second surface-insulation portion made of resin onto the entire surface of said conductive portions while supporting said carrier section with said molding die; and
performing a secondary cutting process in which said first surface-insulation portion is cut so that said carrier section is separated from said conductive portions.

11. The method of manufacturing a semiconductor light-emitting element mounting module according to claim 10, wherein said pair of terminals are formed separately from said conductor plate.

12. The method of manufacturing a semiconductor light-emitting element mounting module according to claim 10, wherein said conductor plate comprises an elongated plate member that extends linearly;
wherein each end of said conductor plate, with respect to the elongated direction of said conductor plate, is provided with said pair of terminals.

13. The method of manufacturing a semiconductor light-emitting element mounting module according to claim 10, wherein said first surface-insulation portion is provided around at least a part of the periphery of said semiconductor light-emitting element, which is connected to said connection surface, with a reflective wall which reflects light that is emitted from said semiconductor light-emitting element.

14. The method of manufacturing a semiconductor light-emitting element mounting module according to claim 13, wherein said reflective wall is annular in shape and surrounds the entire periphery of said semiconductor light-emitting element that is connected to said connection surface.

15. The method of manufacturing a semiconductor light-emitting element mounting module according to claim 10, wherein said conductive portions includes a plurality of said connection surfaces;
wherein a plurality of said cutoff bridges are connected to said plurality of said connection surfaces to integrate adjacent said connection surfaces, and
wherein said primary cutting process separates said adjacent said connection surfaces.

16. A method of manufacturing a semiconductor light-emitting element module, comprising:
the method of manufacturing a semiconductor light-emitting element mounting module according to claim 15;
placing at least one said semiconductor light-emitting element on each of said connection surfaces; and
connecting said semiconductor light-emitting elements to said connection surfaces, and connecting each said adjacent connection surfaces, respectively, to be electrically conductive therebetween.

17. The method of manufacturing the semiconductor light-emitting element module according to claim 16, wherein said connecting of said semiconductor light-emitting elements to said connection surfaces and said connecting of each said adjacent connection surfaces are carried out using wire bonding.

18. The method of manufacturing the semiconductor light-emitting element module according to claim 16, wherein after carrying out said connecting of said semiconductor light-emitting elements to said connection surfaces and said connecting of each said adjacent connection surfaces, the surfaces of said semiconductor light-emitting elements and said wire bonding are covered with a sealant that is formed from a transparent resin.

19. The method of manufacturing the semiconductor light-emitting element module according to claim 16, wherein after carrying out said connecting of said semiconductor light-emitting elements to said connection surfaces and said connecting of each said adjacent connection surfaces, the periphery of said terminals are covered by a terminal covering portion which prevents an external part of each of said terminals from being exposed when said pair of terminals are connected to another pair of terminals or when said pair of terminals are connected to another conductive member.
